(19) United States
(12) Patent Application Publication
(10) Pub. No.: US 2025/0234710 A1
(43) Pub. Date: Jul. 17, 2025

(54) DISPLAY SUBSTRATE AND METHOD OF MANUFACTURING THE SAME, AND DISPLAY DEVICE

(71) Applicants: HEFEI BOE JOINT TECHNOLOGY CO., LTD., Hefei (CN); BOE TECHNOLOGY GROUP CO., LTD., Beijing (CN)

(72) Inventors: Huifeng Wang, Beijing (CN); Hongli Wang, Beijing (CN)

(21) Appl. No.: 18/703,709

(22) PCT Filed: Apr. 4, 2023
(86) PCT No.: PCT/CN2023/086075

§ 371 Date: Apr. 22, 2024

(51) Int. Cl. H10K 59/122; H10K 59/12; H10K 59/124

(52) U.S. Cl. CPC H10K 59/122; H10K 59/1201; H10K 59/124

(57) ABSTRACT

Provided are a display substrate and a method of manufacturing the same, and a display device. The display substrate includes: a base substrate; a planarization layer; a pixel defining layer including a first pixel defining layer and a second pixel defining layer; a first electrode. A vertical spacing between the first surface of first pixel defining layer and the first surface of base substrate is less than a vertical spacing between the first surface of second pixel defining layer and the first surface of base substrate. The first surface of the first pixel defining layer has a first region and second region. An orthographic projection of the electrode via hole on the base substrate is located within an orthographic projection of the second region on the base substrate. A maximum vertical spacing between the second region and the first region is less than or equal to a thickness of the first pixel defining layer in the first region.

### CROSS-REFERENCE TO RELATED APPLICATION

This application is a Section 371 National Stage Application of International Application No. PCT/CN2023/086075, filed on Apr. 4, 2023, entitled “DISPLAY SUBSTRATE AND METHOD OF MANUFACTURING THE SAME, AND DISPLAY DEVICE”, the content of which is hereby incorporated by reference in its entirety.

### TECHNICAL FIELD

The present disclosure relates to a field of display technology, in particular to a display substrate and a method of manufacturing the same, and a display device.

### BACKGROUND

Organic light-emitting diode (OLED) is a type of current type organic light-emitting device, which has advantages of lightweight, wide viewing angle, active light-emitting, continuously adjustable light-emitting color, fast response speed, low energy consumption, simple manufacturing process, high light-emitting efficiency, high brightness, and flexible display, and widely used in various electronic products.

In the manufacturing process of display devices, due to the inclusion of a plurality of film layers used to form structures such as a pixel driving circuit and a driving transistor, the planarity of each film layer structure is greatly affected when forming these structures, ultimately resulting in problems of poor display performance and high manufacturing costs of the display devices.

### SUMMARY

In order to solve at least one aspect of the above problems, embodiments of the present disclosure provide a display substrate and a method of manufacturing the same, and a display device, which may at least improve the display effect of the display device and reduce manufacturing costs.

In an aspect, a display substrate is provided, including: a base substrate including a first surface; a plurality of sub-pixels disposed on a side of the first surface of the base substrate, where the sub-pixel includes a light-emitting device and a pixel driving circuit for driving the light-emitting device, the pixel driving circuit includes a plurality of transistors, and each of the transistors includes a source electrode and a drain electrode; a planarization layer located on a side of the pixel driving circuit away from the base substrate, where the planarization layer is provided with an electrode via hole, and an orthographic projection of the electrode via hole on the base substrate at least partially overlaps with an orthographic projection of the source electrode of at least one transistor or an orthographic projection of the drain electrode of at least one transistor on the base substrate; a pixel defining layer disposed on a side of the planarization layer away from the base substrate, where the pixel defining layer defines a plurality of pixel openings; a first electrode disposed between the planarization layer and the pixel defining layer, where an orthographic projection of the pixel opening on the base substrate is located within an orthographic projection of the first electrode on the base substrate. The pixel defining layer includes a first pixel defining layer and a second pixel defining layer. The first pixel defining layer includes a first surface away from the base substrate. The second pixel defining layer includes a first surface away from the base substrate. A vertical spacing between the first surface of the first pixel defining layer and the first surface of the base substrate is less than a vertical spacing between the first surface of the second pixel defining layer and the first surface of the base substrate. The display substrate includes a first pixel defining portion and a second pixel defining portion. The first pixel defining portion is located in the first pixel defining layer and extends in a first direction. The second pixel defining portion is located in the second pixel defining layer and extends in a second direction. The first direction intersects with the second direction. The first pixel defining portion and the second pixel defining portion define the pixel opening. The first surface of the first pixel defining layer has a first region and a second region. A step difference of the first region is less than a thickness of the first pixel defining layer. A step difference of the second region is less than or equal to a depth of the electrode via hole in the planarization layer. An orthographic projection of the electrode via hole on the base substrate is located within an orthographic projection of the second region on the base substrate. A maximum vertical spacing between the second region of the first surface of the first pixel defining layer and the first region of the first surface of the first pixel defining layer is less than or equal to a thickness of the first pixel defining layer in the first region.

In some exemplary embodiments of the present disclosure, a vertical spacing between the second region of the first surface of the first pixel defining layer and the first region of the first surface of the first pixel defining layer gradually increases from an edge of the second region towards a center of the second region.

In some exemplary embodiments of the present disclosure, the second region of the first surface of the first pixel defining layer protrudes relative to the first region of the first surface of the first pixel defining layer towards a direction away from the base substrate, and a protruding portion includes a protruding point with a maximum spacing from the base substrate.

In some exemplary embodiments of the present disclosure, a vertical spacing between the protruding point and the first region of the first surface of the first pixel defining layer is less than or equal to the thickness of the first pixel defining layer in the first region.

In some exemplary embodiments of the present disclosure, the second region of the first surface of the first pixel defining layer recesses relative to the first region of the first surface of the first pixel defining layer towards a direction close to the base substrate, and a recessing portion includes a recessing point with a minimum vertical spacing from the base substrate.

In some exemplary embodiments of the present disclosure, a vertical spacing between the recessing point and the first region of the first surface of the first pixel defining layer is less than or equal to a thickness of the first pixel defining layer in the first region.

In some exemplary embodiments of the present disclosure, the first pixel defining layer includes a first pixel defining sub-layer. The recessing point is located on the first pixel defining sub-layer. The vertical spacing between the recessing point and the first region of the first surface of the first pixel defining layer is greater than or equal to a thickness of the first pixel defining layer in the first region.

In some exemplary embodiments of the present disclosure, the first pixel defining layer further includes a planarization portion disposed on a side of the first pixel defining sub-layer away from the base substrate. An orthographic projection of the planarization portion on the base substrate is located within an orthographic projection of the electrode via hole on the base substrate.

In some exemplary embodiments of the present disclosure, the planarization portion includes a first surface away from the base substrate. A maximum vertical spacing between a first surface of the planarization portion and the first region of the first surface of the first pixel defining layer is less than the thickness of the first pixel defining layer in the first region.

In some exemplary embodiments of the present disclosure, a vertical spacing between the second region of the first surface of the first pixel defining layer and the first surface of the base substrate gradually increases from the edge of the second region towards the center of the second region.

In some exemplary embodiments of the present disclosure, the vertical spacing between the second region of the first surface of the first pixel defining layer and the first surface of the base substrate gradually decreases from the edge of the second region towards the center of the second region.

In some exemplary embodiments of the present disclosure, a first projection region is formed on the base substrate by the first region of the first pixel defining layer. A second projection region is formed on the base substrate by the second region of the first pixel defining layer. The first electrode includes a first surface away from the base substrate. A step difference of the first surface of the first electrode in the first projection region is less than or equal to the thickness of the first pixel defining layer in the first region.

In some exemplary embodiments of the present disclosure, the planarization layer includes a first surface away from the base substrate. A step difference of the first surface outside the second projection region of the planarization layer is less than or equal to the thickness of the first pixel defining layer in the first region.

In some exemplary embodiments of the present disclosure, a material of the planarization portion includes an organic material or an inorganic material.

In some exemplary embodiments of the present disclosure, the display substrate further includes a second electrode between the first electrode and the source electrode of the transistor or the drain electrode of the transistor. An orthographic projection of the second electrode on the base substrate is located within an orthographic projection of the electrode via hole on the base substrate. The second electrode is configured to electrically connect the first electrode to the source electrode of the transistor or the drain electrode of the transistor.

In some exemplary embodiments of the present disclosure, the orthographic projection of the first electrode on the base substrate partially overlaps with an orthographic projections of a second pixel defining portion adjacent to the first electrode in the first direction on the base substrate.

In some exemplary embodiments of the present disclosure, an orthographic projection of the first pixel defining portion on the base substrate partially overlaps with an orthographic projection of the first electrode adjacent to the first pixel defining portion in the second direction on the base substrate, to form an overlapping region. The electrode via hole is located in the overlapping region.

In some exemplary embodiments of the present disclosure, the first pixel defining layer includes a hydrophilic material. The second pixel defining layer includes a hydrophobic material.

Another aspect of the present disclosure provides a method for manufacturing a display substrate, including: forming a pixel driving circuit for driving a light-emitting device of a plurality of sub-pixels on a side of a first surface of a base substrate, where the pixel driving circuit includes a plurality of transistors, and each of the transistors includes a source electrode and a drain electrode; forming a planarization layer on a side of the pixel driving circuit away from the base substrate, where the planarization layer is provided with an electrode via hole, and an orthographic projection of the electrode via hole on the base substrate at least partially overlaps with an orthographic projection of the source electrode of at least one transistor or an orthographic projection of the drain electrode of at least one transistor on the base substrate; forming a pixel defining layer on a side of the planarization layer away from the base substrate, where the pixel defining layer defines a plurality of pixel openings; forming a first electrode between the planarization layer and the pixel defining layer before forming the pixel defining layer, so that an orthographic projection of the pixel opening on the base substrate is located within an orthographic projection of the first electrode on the base substrate. The forming of the pixel defining layer includes forming a first pixel defining layer and forming a second pixel defining layer. The first pixel defining layer includes a first surface away from the base substrate, and the second pixel defining layer includes a first surface away from the base substrate, the pixel defining layer is formed, so that a vertical spacing between the first surface of the first pixel defining layer and the first surface of the base substrate is less than a vertical spacing between the first surface of the second pixel defining layer and the first surface of the base substrate. The method further includes: forming a first pixel defining portion and forming a second pixel defining portion. The first pixel defining portion is located in the first pixel defining layer and extends in a first direction. The second pixel defining portion is located in the second pixel defining layer and extends in a second direction. The first direction intersects with the second direction. The first pixel defining portion and the second pixel defining portion define the pixel opening. The first surface of the first pixel defining layer has a first region and a second region. A step difference of the first region is less than a thickness of the first pixel defining layer. A step difference of the second region is less than or equal to a depth of the electrode via hole in the planarization layer. An orthographic projection of the electrode via hole on the base substrate is located within an orthographic projection of the second region on the base substrate. A maximum vertical spacing between the second region of the first surface of the first pixel defining layer and the first region of the first surface of the first pixel defining layer is less than or equal to a thickness of the first pixel defining layer in the first region.

In some exemplary embodiments of the present disclosure, forming the first pixel defining layer includes: forming a pixel defining layer material on a side of the planarization layer away from the base substrate; performing an exposure and an etching on the pixel defining layer material to form the first pixel defining layer, where when performing an exposure and an etching on the pixel defining layer material, an exposure amount gradually decreases from an edge of the second region of the first surface of the first pixel defining layer towards a center of the second region of the first surface of the first pixel defining layer.

In some exemplary embodiments of the present disclosure, forming the second pixel defining layer includes: forming a pixel defining layer material on a side of the planarization layer away from the base substrate; performing an exposure and an etching on the pixel defining layer material to form the second pixel defining layer, where when performing an exposure and an etching on the pixel defining layer material, an exposure amount of a region located in the first pixel defining layer is greater than an exposure amount of a region located in the second pixel defining layer.

In some exemplary embodiments of the present disclosure, the method further includes: forming a planarization portion on a side of a first pixel defining sub-layer included in the first pixel defining layer away from the base substrate through an exposure and an etching. An orthographic projection of the planarization portion on the base substrate is located within the orthographic projection of the electrode via hole on the base substrate.

In some exemplary embodiments of the present disclosure, the method further includes: forming a planarization portion on a side of a first pixel defining sub-layer included in the first pixel defining layer away from the base substrate through an inkjet printing. An orthographic projection of the planarization portion on the base substrate is located within the orthographic projection of the electrode via hole on the base substrate.

In some exemplary embodiments of the present disclosure, forming a first pixel defining layer and forming a second pixel defining layer include: forming a pixel defining layer material on a side of the planarization layer away from the base substrate; and performing an exposure and an etching on the pixel defining layer material to simultaneously form the first pixel defining layer and the second pixel defining layer. When performing an exposure and an etching on the pixel defining layer material, an exposure amount gradually decreases in a direction from the first pixel defining layer towards the second pixel defining layer.

In some exemplary embodiments of the present disclosure, the method further includes: forming a second electrode on a side of the planarization layer away from the base substrate through inkjet printing before forming the first electrode. The second electrode is located between the first electrode and the source electrode of the transistor or the drain electrode of the transistor. An orthographic projection of the second electrode on the base substrate is located within the orthographic projection of the electrode via hole on the base substrate. The second electrode is configured to electrically connect the first electrode to the source electrode of the transistor or the drain electrode of the transistor.

In some exemplary embodiments of the present disclosure, forming the first electrode includes: forming the first electrode through exposure process, so that a step difference of a first surface of the first electrode in a first projection region is less than or equal to the thickness of the first pixel defining layer in the first region. The first projection region is formed by projecting the first region of the first pixel defining layer onto the base substrate. The first surface of the first electrode is a surface on a side of the first electrode away from the base substrate.

In some exemplary embodiments of the present disclosure, forming the planarization layer includes: forming the planarization layer through exposure process, so that a step difference of a first surface outside a second projection region of the planarization layer is less than or equal to the thickness of the first pixel defining layer in the first region. The second projection region is formed by projecting the second region of the first pixel defining layer onto the base substrate. The first surface of the planarization layer is a surface on a side of the planarization layer away from the base substrate.

Another aspect of the present disclosure further provides a display device, including a display substrate as described above.

### BRIEF DESCRIPTION OF THE DRAWINGS

Through the following descriptions of the present disclosure with reference to the accompanying drawings, other objectives and advantages of the present disclosure will become more apparent, and may contribute to a comprehensive understanding of the present disclosure.

FIG. 1 schematically shows a schematic top view of a display substrate according to an embodiment of the present disclosure;

FIG. 2A schematically shows a partially enlarged top view of a display substrate according to an embodiment of the present disclosure;

FIG. 2B schematically shows a schematic top view of a three-dimensional structure of FIG. 2A;

FIG. 3A schematically shows a cross-sectional view of a display substrate taken along line A-A in FIG. 2A according to some embodiments of the present disclosure;

FIG. 3B schematically shows a cross-sectional view of a display substrate taken along line A-A in FIG. 2A according to some other embodiments of the present disclosure;

FIG. 3C schematically shows a cross-sectional view of a display substrate taken along line A-A in FIG. 2A according to some yet embodiments of the present disclosure;

FIG. 3D schematically shows a cross-sectional view of a display substrate taken along line A-A in FIG. 2A according to some still embodiments of the present disclosure;

FIG. 4 schematically shows a cross-sectional view of a display substrate taken along line B-B in FIG. 2A according to some other embodiments of the present disclosure;

FIG. 5 schematically shows a flowchart of a method for manufacturing a display substrate according to some embodiments of the present disclosure;

FIG. 6A to FIG. 6D schematically show cross-sectional views of a pixel defining layer formed by a method for manufacturing a display substrate according to some embodiments of the present disclosure;

FIG. 7A to FIG. 7B schematically show cross-sectional views of a pixel defining layer formed by a method for manufacturing a display substrate according to some other embodiments of the present disclosure.

It should be noted that for the sake of clarity, in the accompanying drawings used to describe the embodiments of the present disclosure, dimensions of layers, structures or regions may be enlarged or reduced, that is, these drawings are not drawn according to actual scales.

### DETAILED DESCRIPTION OF EMBODIMENTS

Through embodiments and in conjunction with the accompanying drawings, the technical solution of the present disclosure will be further specifically explained. In the description, the same or similar reference number indicate the same or similar component. The following explanation of the embodiments of the present disclosure with reference to the accompanying drawings is intended to explain the entire inventive concept of the present disclosure, and should not be understood as a limit on the present disclosure.

In addition, in the following detailed description, for the sake of explanation, many specific details are elaborated to provide a comprehensive understanding of the embodiments of the present disclosure. However, it is obvious that one or more embodiments may also be implemented without these specific details.

It should be noted that although the terms “first”, “second”, etc. may be used here to describe various components, members, elements, regions, layers, and/or parts, these components, members, elements, regions, layers, and/or parts should not be limited by these terms. Instead, these terms are used to distinguish one component, member, element, region, layer, and/or part from another component, member, element, region, layer, and/or part. Therefore, for example, the first component, the first member, the first element, the first region, the first layer, and/or the first part discussed below may be referred to as the second component, the second member, the second element, the second region, the second layer, and/or the second part, without departing from the teachings of the present disclosure.

For ease of description, a spatially relational term, e.g., “upper”, “lower”, “left”, “right”, etc. may be used herein to describe a relationship between one element or feature with another element or feature as shown in the drawings. It should be understood that the spatially relational terms are intended to encompass other different orientations of the apparatus in use or operation in addition to an orientation depicted in the drawings. For example, if the apparatus in the drawings is turned over, the elements described as “below” or “beneath” the other elements or features would then be oriented “above” or “on” the other elements or features.

In the present disclosure, the terms “basically”, “about”, “approximately”, “roughly” and other similar terms are used as approximate terms rather than as terms of degree, and they are intended to explain the fixed deviation of measured or calculated values that will be recognized by those of ordinary skill in the art. Taking into account factors such as process fluctuations, measurement problems and errors related to the measurement of a specific amount (i.e., the limitations of the measurement system), the “about” or “approximately” used here includes the stated value, and indicates that the specific value determined by those of ordinary skill in the art is within the acceptable deviation range. For example, “about” may be expressed within one or more standard deviations, or within ±30%, ±20%, ±10%, ±5% of the stated values.

It should be noted that, in this text, the expression “same layer” refers to a layer structure which is formed by forming a layer used to form a specific pattern by the same film-forming process, and then patterning the layer by using the same mask through an one-time patterning process. According to the difference between the specific patterns, the one-time patterning process may include multiple exposures, developments or etching processes, and the specific pattern in the formed layer structure may be continuous or discontinuous. That is, multiple elements, components, structures and/or parts located in the “same layer” are made of the same material and formed by the same composition process. Generally, multiple elements, components, structures and/or parts located in the “same layer” have substantially the same thicknesses.

Those of skill in the art should understand that in this text, unless otherwise defined, the expression of “continuously extending”, “integrated structure”, “entire structure” or similar expressions indicate: a plurality of elements, components, structures and/or parts are located in the same layer, and are formed by the same patterning process in the manufacturing process. There are no intervals or faults between these elements, components, structures and/or parts, but continuously extending structures.

In this text, directional expressions such as “first direction” and “second direction” are used to describe different directions along the pixel region, such as the vertical direction of the pixel region and the horizontal direction of the pixel region. It should be understood that such representation is only an illustrative description, rather than a limit on the present disclosure.

In this text, the terms “first surface” and “second surface” may represent a surface of a film layer facing one direction. For example, the first surface of the base substrate may represent an upper side surface in a direction perpendicular to the plane where the base substrate is located in. The second surface of the base substrate may represent a lower side surface in a direction perpendicular to the plane where the base substrate is located in.

In this text, the terms “first region” and “second region” may represent a region morphology of a certain surface of the film layer. The first region may, for example, represent a region that a certain surface morphology of the film layer is planarized. The second region may, for example, represent a region that a certain surface morphology of the film layer is not planarized (for example, there is a certain step difference change). The first region and the second region may be, for example, surfaces with the same displacement, but are located in different regions.

In this text, the terms “step difference” may represent a height difference between different height points on one surface. For example, when there are a high point and a low point in one step region of the surface of an object, the step difference of the one step region the surface of the object is a vertical spacing between the high point and the low point. When one surface is not a planarized surface, the step difference of this surface is the vertical spacing between higher points and lower points at different positions.

In the related art, OLED devices currently have problems such as short display life, long-term display leading to display degradation, and poor pixel uniformity in the process of manufacturing the device. In order to solve the aforementioned problems in the related art, an embodiment of the present disclose provides a display substrate, including but not limited to: a base substrate including a first surface; a plurality of sub-pixels disposed on a side of the first surface of the base substrate, where the sub-pixel includes a light-emitting device and a pixel driving circuit for driving the light-emitting device, the pixel driving circuit includes a plurality of transistors, and each of the transistors includes a source electrode and a drain electrode; a planarization layer located on a side of the pixel driving circuit away from the base substrate, where the planarization layer is provided with an electrode via hole, and an orthographic projection of the electrode via hole on the base substrate at least partially overlaps with an orthographic projection of the source electrode of at least one transistor or an orthographic projection of the drain electrode of at least one transistor on the base substrate; a pixel defining layer disposed on a side of the planarization layer away from the base substrate, where the pixel defining layer defines a plurality of pixel openings; a first electrode disposed between the planarization layer and the pixel defining layer, where an orthographic projection of the pixel opening on the base substrate is located within an orthographic projection of the first electrode on the base substrate. The pixel defining layer includes a first pixel defining layer and a second pixel defining layer. The first pixel defining layer includes a first surface away from the base substrate. The second pixel defining layer includes a first surface away from the base substrate. A vertical spacing between the first surface of the first pixel defining layer and the first surface of the base substrate is less than a vertical spacing between the first surface of the second pixel defining layer and the first surface of the base substrate. The display substrate includes a first pixel defining portion and a second pixel defining portion. The first pixel defining portion is located in the first pixel defining layer and extends in a first direction. The second pixel defining portion is located in the second pixel defining layer and extends in a second direction. The first direction intersects with the second direction. The first pixel defining portion and the second pixel defining portion define the pixel opening. The first surface of the first pixel defining layer has a first region and a second region. A step difference of the first region is less than a thickness of the first pixel defining layer. A step difference of the second region is less than or equal to a depth of the electrode via hole in the planarization layer. An orthographic projection of the electrode via hole on the base substrate is located within an orthographic projection of the second region on the base substrate. A maximum vertical spacing between the second region of the first surface of the first pixel defining layer and the first region of the first surface of the first pixel defining layer is less than or equal to a thickness of the first pixel defining layer in the first region.

According to the embodiment of the present disclosure, through arranging the pixel defining layer to include a first pixel defining layer and a second pixel defining layer, and the vertical spacing between the first surface of the first pixel defining layer and the first surface of the base substrate is less than the vertical spacing between the first surface of the second pixel defining layer and the first surface of the base substrate, so as to achieve the arrangement of pixel defining layers of different heights. Pixels in the first direction are spaced apart by the second pixel defining layer, while pixels in the second direction are spaced apart by the first pixel defining layer. At the same time, since a height of the first pixel defining layer is lower than a height of the second pixel defining layer, so as to achieve that when performing inkjet printing on pixel light-emitting regions, ink may flow between pixels in the second direction, ensure the planarity and the uniformity of a luminescent material layer of pixels in the second direction, thereby improving the display effect of the display device.

In the embodiment of the present disclosure, a pixel driving circuit is provided between the planarization layer and the base substrate. The wiring of the pixel driving circuit causes uneven film thickness of the planarization layer located on a side of the pixel driving circuit away from the base substrate. Therefore, when forming the pixel defining layer, by using different exposure processes, the maximum vertical spacing between the second region of the first surface of the first pixel defining layer and the first region of the first surface of the first pixel defining layer is less than the thickness of the first pixel defining layer in the first region. It is possible to achieve that the vertical spacing between the second region located at the position of the electrode via hole and the first region at other positions is smaller. On the one hand, it is possible to effectively improve the problem of the uneven film thickness on a side of the planarization layer away from the base substrate and the planarization layer caused by the wiring of the pixel driving circuit. At the same time, it may prevent ink from remaining in the recessed region at the electrode via hole when inkjet printing is performed on the pixel light-emitting region, which leads to the problem of ink waste, and effectively improve the display effect of the display device.

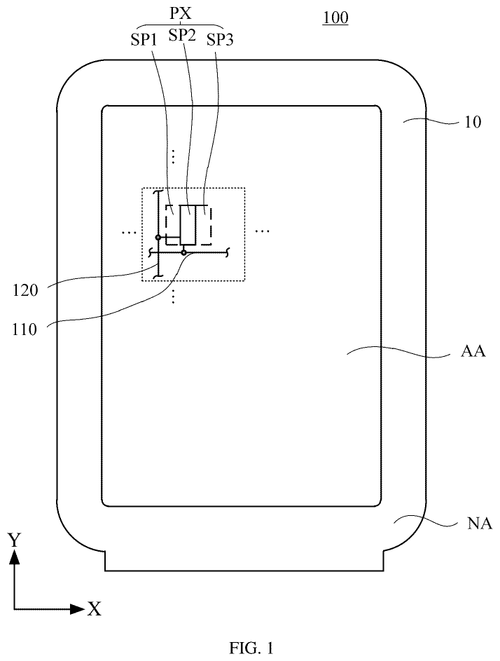

The display substrate of the embodiment of the present disclosure will be described in detail below with reference to FIG. 1 to FIG. 4.

FIG. 1 schematically shows a schematic top view of a display substrate according to an embodiment of the present disclosure. With reference to FIG. 1, the display substrate according to the embodiment of the present disclosure may include a base substrate 10 and a pixel unit PX disposed on the base substrate 10.

The display substrate 100 may include a display region AA and a non-display region NA. The display region AA may be a region providing with a pixel unit PX for displaying an image. Each pixel unit PX will be described later. The non-display region NA is a region providing without the pixel unit PX, which may be a region where no image is displayed. The non-display region NA corresponds to the border in the final display device, and a width of the border may be determined based on a width of the non-display region NA.

The display region AA may have various shapes. For example, the display region AA may be provided in various shapes such as a closed polygon including straight edges (such as rectangle), a circle or ellipse, etc. including curved edges, and a semicircle or semi-ellipse, etc. including straight edges and curved edges. In the embodiment of the present disclosure, the display region AA is provided as a region with a quadrilateral shape including straight edges. It should be understood that this is only an exemplary embodiment of the present disclosure, rather than a limit on the present disclosure.

The non-display region NA may be disposed on at least one side of the display region AA. In the embodiment of the present disclosure, the non-display region NA may surround a periphery of the display region AA. In the embodiment of the present disclosure, the non-display region NA may include a lateral portion extending in the first direction X and a longitudinal portion extending in the second direction Y.

The pixel unit PX is disposed in the display region AA. The pixel unit PX is the smallest unit used to display images and a plurality of pixel units PX may be provided. For example, the pixel unit PX may include a light-emitting device that emits white light and/or colored light.

A plurality of pixel units PX may be provided and arranged in a matrix form along rows extending in the first direction X and columns extending in the second direction Y. However, the embodiments of the present disclosures do not specifically limit the arrangement form of the pixel units PX, and the pixel units PX may be arranged in various forms. For example, the pixel unit PX may be arranged such that a direction inclined relative to the first direction X and the second direction Y becomes a column direction, and a direction intersecting with the column direction becomes a row direction.

That is to say, the plurality of pixel units PX are arranged in an array along the first direction X and the second direction Y, so as to form a plurality of rows of pixel units and a plurality of columns of pixel units.

One pixel unit PX may include a plurality of sub-pixels. For example, one pixel unit PX may include three sub-pixels, that is, a first sub-pixel SP1, a second sub-pixel SP2 and a third sub-pixel SP3. For example, the first sub-pixel SP1 may be a red sub-pixel, the second sub-pixel SP2 may be a green sub-pixel, and the third sub-pixel SP3 may be a blue sub-pixel.

It should be noted that in the embodiment of the present disclosure, there is no special limitation on the number of sub-pixels included in one pixel unit, and it is not limited to the three mentioned above.

For example, in the exemplary embodiment shown in FIG. 1, the wires of the pixel driving circuit in the display substrate is schematically shown, including, for example, a scanning control signal line 110 and a data line 120. That is, the base substrate of the display substrate 100 includes a first surface. The display substrate 100 may further include: a plurality of scanning control signal lines 110 and a plurality of data lines 120 which are disposed on the first surface of the base substrate. The plurality of scanning control signal lines 110 supply scanning control signals to the plurality of rows of pixel units, respectively. The plurality of data lines 120 supply data signals to the plurality of columns of pixel units, respectively. The scanning control signal line 110 extends in the first direction X. The plurality of scanning control signal lines 110 are arranged at intervals in the second direction Y. The data line 120 extends in the second direction Y. The plurality of data lines 120 are arranged at intervals in the first direction X.

For example, the scanning control signal line 110 may be a representative of a lateral wire, and the data line 120 may be a representative of a longitudinal wire. It should be understood that the lateral wire may also include wires of other types or used to supply other signals, and the longitudinal wire may also include wires of other types or used to supply other signals.

Each sub-pixel may include a light-emitting device and a pixel driving circuit for driving the light-emitting device. For example, in an OLED display substrate or display panel, the light-emitting device of the sub-pixel may include an anode, a luminescent material layer and a cathode, which are disposed in a stack. The anodes of the light-emitting devices of respective sub-pixels are spaced apart and arranged in a matrix form along rows extending in the first direction X and columns extending in the second direction Y.

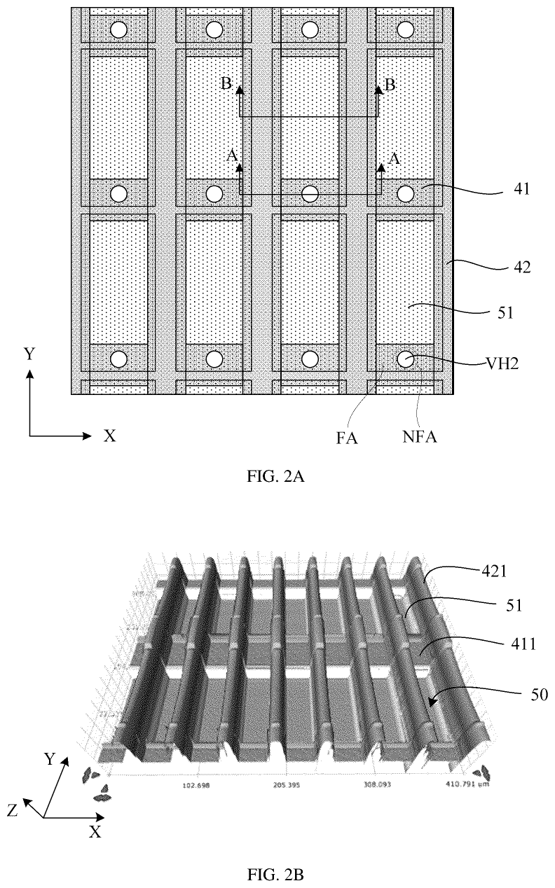

FIG. 2A schematically shows a partially enlarged top view of a display substrate according to an embodiment of the present disclosure, showing a partially enlarged view of an M region in FIG. 1, including a plurality of sub-pixels arranged in an array along the first direction X and the second direction Y. FIG. 2B schematically shows a schematic top view of a three-dimensional structure of FIG. 2A, schematically showing the three-dimensional structure of a pixel defining layer defining a plurality of pixel openings.

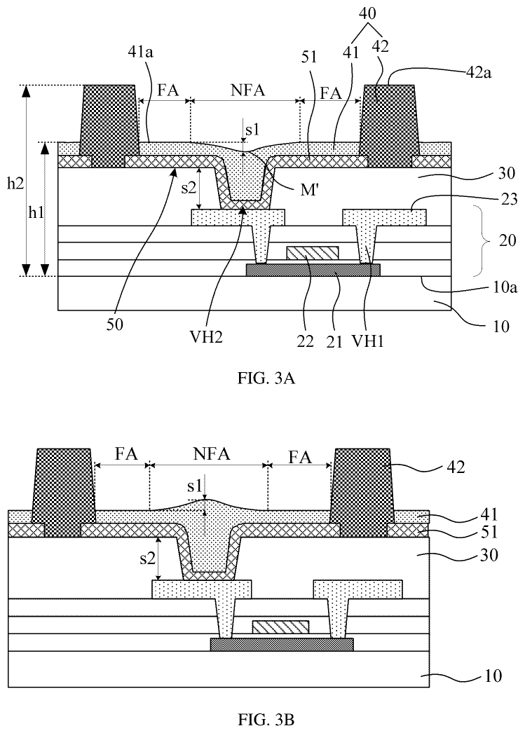

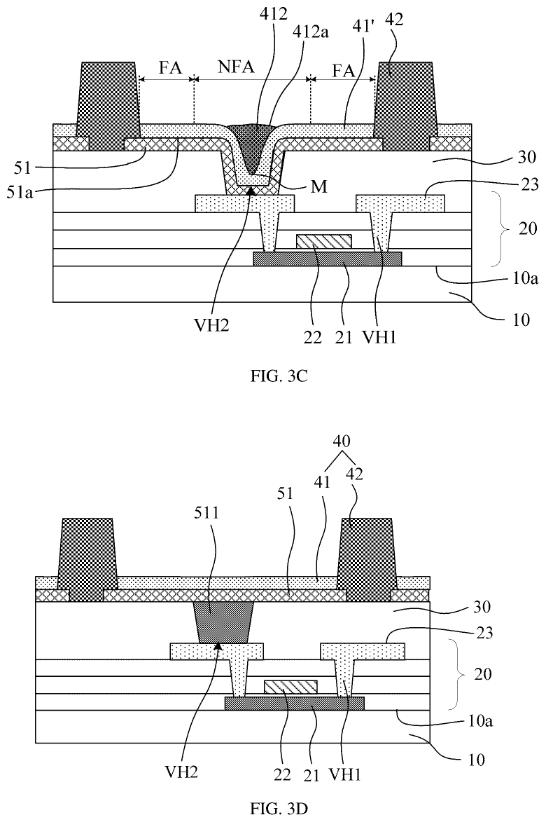

FIG. 3A schematically shows a cross-sectional view of a display substrate taken along line A-A in FIG. 2A according to some embodiments of the present disclosure. FIG. 3B schematically shows a cross-sectional view of a display substrate taken along line A-A in FIG. 2A according to some other embodiments of the present disclosure. FIG. 3C schematically shows a cross-sectional view of a display substrate taken along line A-A in FIG. 2A according to some yet embodiments of the present disclosure. FIG. 3D schematically shows a cross-sectional view of a display substrate taken along line A-A in FIG. 2A according to some still embodiments of the present disclosure.

The structure of the display substrate according to some embodiments of the present disclosure will be described below with reference to FIG. 2A to FIG. 3A. As shown in FIG. 3A, the display substrate 100 includes a base substrate 10, a pixel driving circuit 20, a planarization layer 30, a pixel defining layer 40 and a light-emitting device 50.

The base substrate 10 includes a first surface 10a. The first surface 10a is, for example, an upper surface of the base substrate 10. An upper side of the first surface 10a is provided with a plurality of sub-pixels included in the pixel unit PX, for example, which may be directly disposed on the first surface 10a, or may also be disposed on a side of the first surface 10a. A plurality of other film layers may also be included between the sub-pixels and the first surface 10a. As shown in FIG. 2A, a plurality of sub-pixels are arranged in an array along the first direction X and the second direction Y on the base substrate. Among the plurality of sub-pixels included in the pixel unit PX, each sub-pixel includes a pixel driving circuit 20 and a light-emitting device 50. The pixel driving circuit 20 is used to drive the light-emitting device 50 to emit light. The pixel driving circuit includes one or more transistors. Each of the transistors includes a source electrode or a drain electrode. Through inputting different electrical signals into one or more transistors, a light-emitting control of the light-emitting device 50 is achieved. In this embodiment, the first direction X intersects with the second direction Y, and an angle between the first direction X and the second direction Y is a right angle. In an optional embodiment, the angle between the first direction X and the second direction Y may be an acute angle.

As shown in FIG. 3A, a side of the base substrate 10, for example, a side of the first surface 10a is provided with a pixel driving circuit 20. The pixel driving circuit 20 includes wires disposed on different film layers, such as a semiconductor layer 21, a gate layer 22 and a source drain layer 23. The source drain layer 23 is electrically connected to the semiconductor layer 21 of the driving circuit 20 through a connecting via hole VH1.

A planarization layer 30 is provided on a side of the pixel driving circuit 20 away from the base substrate 10. An electrode via hole VH2 is provided on the planarization layer 30. An orthographic projection of the electrode via hole VH2 on the base substrate 10 at least partially overlaps with an orthographic projection of the source electrode of at least one transistor or an orthographic projection of the drain electrode of at least one transistor on the base substrate 10.

The pixel defining layer 40 is disposed on a side of the planarization layer 30 away from the base substrate 10. The pixel defining layer defines a plurality of pixel openings. The plurality of pixel openings are used to be filled with the luminescent material.

A first electrode 51 is provided on a side of the planarization layer 30 away from the base substrate 10. The first electrode 51 is located between the planarization layer 30 and the pixel defining layer 40. The first electrode 51 is, for example, an anode of the light-emitting device 50. As shown in FIG. 2A, an orthographic projection of the pixel opening on the base substrate is located within an orthographic projection of the first electrode 51 on the base substrate, that is, an area of the pixel opening is less than an area of the first electrode 51, so that the luminescent material provided in the pixel opening may fully contact with the first electrode, the luminescent material emits light more uniformly when powered on, thereby improving the display effect.

The first electrode 51 is electrically connected to the source electrode of a transistor or the drain electrode of a transistor through the electrode via hole VH2, thereby controlling the luminescent material in the light-emitting device 50 to emit light or not emit light in a case that the transistor is turned on or turned off.

As shown in FIG. 2A to FIG. 3A, the pixel defining layer 40 includes a first pixel defining layer 41 and a second pixel defining layer 42. The first pixel defining layer 41 includes a first surface 41a away from the base substrate, and the second pixel defining layer 42 includes a first surface 42a away from the base substrate. A vertical spacing h1 between the first surface 41a of the first pixel defining layer 41 and the first surface 10a of the base substrate is less than a vertical spacing h2 between the first surface 42a of the second pixel defining layer 41 and the first surface 10a of the base substrate. Therefore, when a luminescent material layer is formed in the pixel opening defined by the first pixel defining layer 41 and the second pixel defining layer 42, for example, through inkjet printing, it is possible to cause the ink of the luminescent material to overflow an obstruction of the first pixel defining layer 41 under an obstruction of the second pixel defining layer 42, and flow in the plurality of pixel openings, thereby ensuring the planarity of the luminescent material layer and the uniformity of the plurality of pixels. For example, when there is a large amount of ink in the luminescent material in some pixel openings, the ink of the luminescent material may overflow the obstruction of the first pixel defining layer and flow into other pixel openings, thereby improving the display effect of the display device.

In some embodiments of the present disclosure, the first pixel defining layer includes a hydrophilic material, and the second pixel defining layer includes a hydrophobic material.

For example, the first pixel defining layer uses a hydrophilic material. When inkjet printing the ink of the luminescent material, the printed ink will flow normally above the first pixel defining layer and will not accumulate. A contact angle between the first pixel defining layer and the printed ink is less (for example, less than 5 degrees), so that the printed ink does not accumulate above the first pixel defining layer, thereby improving the uniformity of the luminescent material layer formed by printing.

For example, the second pixel defining layer uses a hydrophobic material. When inkjet printing the ink of the luminescent material, the ink located within the pixel opening and in contact with the second pixel defining layer will not have a climbing effect on the second pixel defining layer in the pixel opening. That is, the ink in contact with the second pixel defining layer forms a luminescent material layer in the pixel opening with better planarity. When the second pixel defining layer uses a hydrophobic material, the contact angle between the ink and the second pixel defining layer is generally greater, such as greater than 45 degrees.

In the embodiment of the present disclosures, components of the hydrophilic material and the hydrophobic material may be the same components, and the only difference lies in the fluorine content. In other optical embodiment, the components of the hydrophilic material and the hydrophobic material may be different.

As shown in FIG. 2B, the display substrate 100 includes a first pixel defining portion 411 located in the first pixel defining layer 41 and a second pixel defining portion 421 located in the second pixel defining layer 42. The first pixel defining portion 411 extends in the first direction X, and the second pixel defining portion 421 extends in the second direction Y. The first pixel defining portion 411 and the second pixel defining portion 421 jointly define the pixel opening. A height of the first pixel defining portion 411 in a third direction Z is less than a height of the second pixel defining portion 421 in the third direction Z.

According to the embodiment of the present disclosure, by setting the vertical spacing h1 between the first surface 41a of the first pixel defining layer 41 and the first surface 10a of the base substrate to be less than the vertical spacing h2 between the first surface 42a of the second pixel defining layer and the first surface 10a of the base substrate, when ink containing luminescent materials is inkjet printed into the pixel opening defined by the first pixel defining portion 411 and the second pixel defining portion 421, a horizontal plane of the ink in the pixel opening is higher than the height of the first pixel defining portion 411, the ink may flow in different pixel openings in the second direction Y, thereby ensuring that the horizontal plane height of the ink in the pixel in the second direction Y is the same, improving the uniformity of filling of the luminescent material in the pixel opening, and improving the display effect of the display device.

As shown in FIG. 3A, the first surface 41a of the first pixel defining layer 41 has a first region FA and a second region NFA. An orthographic projection of the electrode via hole VH2 on the base substrate 10 is located within an orthographic projection of the second region NFA on the base substrate 10. In this embodiment, a step difference of the first region is less than the thickness of the first pixel defining layer in the first region. A step difference of the second region is less than or equal to a depth of the electrode via hole VH2 in the planarization layer. The depth refers to the dimension in the third direction Z.

For example, the first region refers to a region that is relatively planarized relative to the second region, that is, the first region is not a completely planarized region, that is, the step difference of the first region is less, while the step difference of the second region is greater. Specifically, the first region may refer to, for example, the region away from the first pixel defining layer 41 away from a peripheral side of the electrode via hole VH2. The second region may refer to, for example, the region close to or located at the peripheral side or inside the electrode via hole VH2.

The first electrode 51 is electrically connected to the source electrode of a transistor or the drain electrode of a transistor through the electrode via hole VH2. When the first pixel defining layer 41 is formed on a side of the first electrode 51 away from the base substrate 10, since the electrode via hole VH2 has a certain depth, the formed first pixel defining layer 41 is at a position away from the electrode via hole on the peripheral side of the electrode via hole, which is the first region FA. The formed first pixel defining layer 41 is not affected by the electrode via hole VH2. At a position close to the peripheral side of the electrode via hole VH2 and inside the electrode via hole VH2, due to the influence of the electrode via hole, the formed first pixel defining layer 41 has a certain second region. In order to prevent a negative impact of the electrode via hole VH2 on the display effect of the display device, the electrode via hole VH2 is disposed between the first pixel defining layer 41 and the planarization layer 30, that is, the orthographic projection of the electrode via hole VH2 on the base substrate 10 is located within the orthographic projection of the second region NFA on the base substrate 10. Compared to disposing the electrode via hole VH2 at other positions, the impact of the electrode via hole VH2 on the planarity of the luminescent material in the pixel opening may be reduced, and the display effect of the light-emitting device may be improved.

In some embodiments of the present disclosure, the maximum vertical spacing between the second region of the first surface of the first pixel defining layer and the first region of the first surface of the first pixel defining layer is less than or equal to the thickness of the first pixel defining layer in the first region. That is, on the first surface of the first pixel defining layer, the vertical spacing between the second region and the first region is less. After the first pixel defining layer and the second pixel defining layer are formed, a luminescent material layer is continued to be formed in subsequent processes, more luminescent material will not remain in the second region, and at the same time, the film layer formed on a side of the first pixel defining layer away from the base substrate will be more uniform, thereby improving the display effect of the display device, and avoid the problem of ink remaining in the second region caused by ink printing of the luminescent material.

As shown in FIG. 3A, the maximum vertical spacing between the second region NFA of the first surface 41a of the first pixel defining layer 41 and the first region FA of the first surface 41a of the first pixel defining layer 41 is s1. For example, the thickness of the first pixel defining layer in the first region FA is less than the thickness of the first pixel defining layer in the second region NFA, that is, the first pixel defining layer in the electrode via hole VH2 has a thicker thickness. The thickness of the pixel defining layer in other regions is less than the thickness of the first pixel defining layer in the electrode via hole VH2. Through limiting s1 to be less than the thickness of the first pixel defining layer in the first region, the impact of the electrode via hole VH2 on the planarity of the upper film layer may be reduced. When forming the first pixel defining layer 41, the filled thickness of the material forming the first pixel defining layer at the position of the electrode via hole VH2 (thickness along the third direction) is greater than the filled thickness of the first pixel defining layer in regions such as the first region FA. The electrode via hole VH2 is filled, so that the step difference of the first pixel defining layer 41 at the electrode via hole VH2 is less, thereby reducing the problem of ink accumulating close to the electrode via hole VH2 when forming a luminescent material layer through inkjet printing, and preventing ink waste. In addition, by achieving a less step difference in the first pixel defining layer at the electrode via hole VH2, it is possible to reduce the residual ink when flowing on the first pixel defining layer 41, and alleviate the problem of the uneven film thickness of the luminescent material layer between different pixels in the second direction Y, thereby improving the display effect of the light-emitting device.

For example, if the spacing s1 of the second region NFA at the electrode via hole VH2 is greater (such as greater than the thickness of the first pixel defining layer in the first region), when there is more ink remaining in this region used to form the luminescent material layer, other regions do not have enough ink filling, resulting in problems such as the display effect of the manufactured luminescent device is uneven.

In some embodiments of the present disclosure, the thickness of the first pixel defining layer is between 100 nm and 2000 nm. For example, in an embodiment, if the thickness of the first pixel defining layer in the first region FA is 100 nm, the maximum vertical spacing s1 between the first region FA of the first pixel defining layer and the second region NFA of the first pixel defining layer is less than or equal to 100 nm. For example, s1 is 50 nm. According to the embodiment of the present disclosure, by setting s1 to be less than the thickness of the first pixel defining layer in the first region, it may be ensured that there is no significant size change in the first pixel defining layer at the position of the electrode via hole, and the display effect of the light-emitting device may be effectively improved.

For example, the first region FA may be further away from the base substrate than the second region NFA (as shown in FIG. 3A). For example, the second region NFA may be recessed towards a direction of the base substrate. Alternatively, the first region FA may be closer to the base substrate than the second region (as shown in FIG. 3B). For example, the second region NFA may protrude away from the direction of the base substrate.

In some embodiments of the present disclosure, as shown in FIG. 2A, the second region NFA of the first surface of the first pixel defining layer 41 may be, for example, the region surrounding the peripheral side of the electrode via hole VH2 (for example, as shown in the circular dotted box). The first region FA of the first surface of the first pixel defining layer 41 may be, for example, the region of the peripheral side of the second region.

In some embodiments of the present disclosure, an outline contour of the second region NFA is related to an outline contour of the electrode via hole VH2. For example, when the electrode via hole VH2 is in a cylindrical shape, the second region NFA is a circular region formed around the cylindrical electrode via hole VH2. For example, the electrode via hole VH2 is in a prismatic shape, and the second region is a polygonal region formed around the prismatic electrode via hole VH2.

In some embodiments of the present disclosure, the vertical spacing between the second region NFA of the first surface 41a of the first pixel defining layer and the first region FA of the first surface 41a of the first pixel defining layer gradually increases from an edge of the second region NFA towards a center of the second region.

For example, the second region NFA may protrude upwards relative to the base substrate in the third direction, or be recessed downwards relative to the base substrate in the third direction. The changes of the second region are gradual, so that the problem of significant reduction of local display effect caused by the rapid change of the region may be alleviated, that is, the problem of display effect reduction caused by the uneven thickness of the upper film layer due to the rapid change of the size of the second region NFA may be reduced.

In some embodiments of the present disclosure, as shown in FIG. 3A, the second region NFA of the first surface 41a of the first pixel defining layer 41 is recessed towards a direction close to the base substrate 10 relative to the first region FA of the first surface 41a of the first pixel defining layer 41. The second region NFA of the first pixel defining layer is closer to the base substrate 10 than the first region FA of the first pixel defining layer.

For example, the vertical spacing between the second region NFA of the first surface of the first pixel defining layer and the first surface of the base substrate gradually decreases from the edge of the second region towards the center of the second region.

In some embodiments of the present disclosure, as shown in FIG. 3B, the second region NFA of the first surface 41a of the first pixel defining layer 41 protrudes in a direction away from the base substrate relative to the first region FA of the first surface 41a of the first pixel defining layer 41. The second region NFA of the first pixel defining layer is further away from the base substrate 10 than the first region FA of the first pixel defining layer.

For example, the vertical spacing between the second region of the first surface of the first pixel defining layer and the first surface of the base substrate gradually increases from the edge of the second region towards the center of the second region.

By adopting the structure shown in FIG. 3B, on the one hand, it may avoid the problem of ink waste caused by ink remaining in the second region NFA when inkjet printing forms a luminescent material layer. On the other hand, since the first region FA of the first surface 41a of the first pixel defining layer 41 is closer to the base substrate than the second region NFA, the ink of the luminescent material located in different pixel openings in the second direction Y may flow in different pixel openings through the first region, improving the uneven film thickness of the luminescent material layer between different pixels in the second direction Y, thereby improving the display effect of the light-emitting device.

In some embodiments of the present disclosure, as shown in FIG. 3C, the first pixel defining layer 41 of the display substrate may specifically include a first pixel defining sub-layer 41′ and a planarization portion 412 located on a side of the first pixel defining sub-layer 41′ away from the base substrate. The second region NFA of the first surface of the first pixel defining layer is recessed towards the direction close to the base substrate 10 relative to the first region FA of the first surface of the first pixel defining layer. A recessed portion includes a recessed point. A vertical spacing between the recessed point and the base substrate is the smallest relative to the vertical spacing between other recessed portions and the base substrate. An orthographic projection of the planarization portion 412 on the base substrate is located within the orthographic projection of the electrode via hole VH2 on the base substrate.

In an embodiment of the present disclosure, as shown in FIG. 3A, the vertical spacing between the recessed point M′ and the first region of the first surface of the first pixel defining layer is less than or equal to the thickness of the first pixel defining layer in the first region, that is, the size of the recessed point M′ included in the recessed portion recessed downward is less, compared to the thickness of the first pixel defining layer in the first region.

In another embodiment of the present disclosure, as shown in FIG. 3C, the vertical spacing between the recessed point M and the first region of the first surface of the first pixel defining layer is greater than or equal to the thickness of the first pixel defining layer in the first region. That is, the size of the recessed point M included in the recessed portion recessed downward is large, and greater than the thickness of the first pixel defining layer in the first region. In this case, a planarization portion 412 requires to be disposed on an upper side of the recessed point M, so as to reduce the impact of the recessed portion on the planarity of the upper film layer due to being recessed. The planarization portion 412 is located in the recessed region of the first pixel defining layer 41 at the electrode via hole VH2. When there is a large recess of the first pixel defining layer 41 at the electrode via hole VH2, by disposing the planarization portion 412 on a side of the first pixel defining layer 41 away from the base substrate, the recessed region may be filled in, thereby preventing the problem of the uneven film thickness of the luminescent material layer formed in different pixel openings caused by the ink remained in the recessed region when inkjet printing the ink of the luminescent material.

In some embodiments of the present disclosure, as shown in FIG. 3C, the planarization portion 412 includes a first surface 412a away from the base substrate. The maximum vertical spacing between the first surface 412a of the planarization portion 412 and the first region FA of the first surface 41a of the first pixel defining layer 41 is less than the thickness of the first pixel defining layer in the first region. The first pixel defining layer includes a first pixel defining sub-layer 41′ and a planarization portion 42. Since the size of the recess of the first pixel defining sub-layer 41′ towards the direction of the base substrate 10 in the electrode via hole VH2 region, a planarization portion 412 is disposed on a side of the first pixel defining sub-layer 41′ away from the base substrate 10, so as to fill the recessed portion and ensure the planarity of the first pixel defining layer in the second region NFA.

For example, when filling the second region NFA of the first pixel defining layer 41 in the electrode via hole VH2, the planarization portion 412 may, for example, be completely filled or partially filled, thereby alleviating or eliminating the problem of ink remaining of the luminescent material caused by the first pixel defining layer 41 in the second region NFA.

For example, the first surface 412a of the planarization portion 412 may be higher than the plane where the first region of the first pixel defining layer 41 is located in the third direction. Alternatively, the first surface 412a of the planarization portion 412 may be equal to or lower than the plane where the first region of the first pixel defining layer 41 is located in the third direction.

In some embodiments of the present disclosure, the planarization portion 412 may, for example, be formed by a lithography process or an inkjet printing process. The material forming the planarization portion 412 may, for example, be the same as the material of the first pixel defining layer 41. Alternatively, similar material systems may be used, such as polyimide, sulfonimide, epoxy resin, and other materials.

For example, a material of the planarization portion includes an organic material or an inorganic material.

For example, the inorganic material includes silicon nitride, and the organic material includes methyl methacrylate, etc.

As shown in FIG. 2A and FIG. 2B, an orthographic projection of the first electrode 51 on the base substrate partially overlaps with an orthographic projection of the second pixel defining portion adjacent to the first electrode 51 in the first direction X on the base substrate. That is, as shown in FIG. 2A, a part of the first electrode 51 is located in the pixel opening. In a direction parallel to the first direction X, the first electrode 51 has a portion extending towards two sides of the pixel opening. The extending portion overlaps with the second pixel defining portion 421 of the second pixel defining layer 42.

An orthographic projection of the first pixel defining portion 411 of the first pixel defining layer 41 partially overlaps with an orthographic projection of the first electrode 51 adjacent to the first pixel defining portion 411 in the second direction Y on the base substrate, to form an overlapping region. The electrode via hole is located in the overlapping region.

A part of the first electrode 51 is located in the pixel opening, and other parts overlaps with the first pixel defining portion 411 of the first pixel defining layer 41 on the periphery side and the second pixel defining portion 421 of the second pixel defining layer 42. The first pixel defining portion 411 and the second pixel defining portion 421 define the pixel opening, so as to accommodate the luminescent material.

In some embodiments of the present disclosure, the first region FA of the first pixel defining layer forms a first projection region (i.e. the region on a lower side of FA) on the base substrate. The second region NFA of the first pixel defining layer forms a second projection region (i.e. the region on a lower side of NFA) on the base substrate. The first electrode 51 includes a first surface 51a away from the base substrate 10. The step difference of the first surface 51a of the first electrode in first projection region is less than or equal to the thickness of the first pixel defining layer 41 in the first region FA, that is, the step difference of the first surface 51a except the second projection region of the first electrode 51 is less, thereby not affecting the uniformity of the subsequent film layer formed on a side of the first electrode 51 away from the base substrate 10. Through such structure, when inkjet printing the luminescent material in the pixel opening, the luminescent material in the pixel opening may have a certain thickness, thereby preventing the problem of uneven luminescent material in the pixel opening caused by manufacturing process deviations.

For example, the pixel opening has an orthographic projection on the base substrate. The first region of the first pixel defining layer forms a first projection region on the base substrate. The second region of the first pixel defining layer forms a second projection region on the base substrate. The wires of the driving circuit in the first projection region and the second projection region will affect the step difference of the first surface of the first electrode, thereby causing corresponding planarization region and uneven region are formed on the first surface of the first electrode, when the first electrode is formed on a side of the driving circuit away from the base substrate. For example, when the driving circuit has more wires in the region of the orthographic projection of the pixel opening, an uneven region will appear at this position, and a planarization region will appear at a position with less wires, thereby resulting in a step difference on the first surface of the first electrode. In this regard, when forming the first electrode material in the pixel opening, through the methods of digital exposure or regional exposure, the vertical spacing between the second region of the first electrode and the first region of the first electrode may be reduced, thereby improving the display effect of the light-emitting device. For example, when forming the first electrode, the exposure amount of the uneven region is greater than the exposure amount of the planarization region, so that the etching amount of the uneven region is greater than the etching amount of the planarization region, and the step difference of the surface of the first electrode in the first projection region is less than or equal to the thickness of the first pixel defining layer in the first region. Through reducing the step difference of the first surface of the first electrode in the first projection region when forming the first electrode, better planarity is achieved when other film layers are formed on the upper side of the first electrode away from the base substrate.

In some embodiments of the present disclosure, the planarization layer includes a first surface away from the base substrate, and the step difference of the first surface outside the second projection region of the planarization layer is less than the thickness of the first pixel defining layer in the first region.

For example, the wires of the pixel driving circuit may cause a certain high and low change in the thickness of each film layer. A planarization layer is formed on a side of the pixel driving circuit away from the base substrate. When forming the planarization layer, due to the influence of the wires of the pixel driving circuit, the first surface of the formed planarization layer has a planarization region and an uneven region. For example, through the methods of regional exposure or digital exposure, the step difference of the first surface outside the second projection region of the planarization layer is less than or equal to the thickness of the first pixel defining layer in the first region, thereby ensuring the thickness of the planarization layer in the first projection region. It is convenient to prevent the step difference between the planarization region and the uneven region from further increasing in the subsequent film layer formation process, and effectively suppress the problem of deterioration of the display effect of the light-emitting device.

In some embodiments of the present disclosure, as shown in FIG. 3D, the display substrate 100 further includes a second electrode 511 between the first electrode 51 and the source electrode of the transistor or the drain electrode of the transistor. An orthographic projection of the second electrode 511 on the base substrate is located within an orthographic projection of the electrode via hole VH2 on the base substrate. The second electrode 511 is used to electrically connect the first electrode 51 to the source electrode of the transistor or the drain electrode of the transistor.

After forming the planarization layer, a second electrode 511 is formed in the electrode via hole through the methods of exposure etching or inkjet printing, that is, the second electrode 511 is located in the electrode via hole. By forming the second electrode 511, the planarity of the first surface of the first pixel defining portion in the first pixel defining layer is better. When forming a luminescent material layer through inkjet printing process, the planarity of the luminescent material layer may be improved and the display effect of the light-emitting device may be improved.

For example, the second electrode is formed by etching at the position of the electrode via hole through the method of exposure etching.

For example, a second electrode is formed by inkjet printing the material of the second electrode into the electrode via hole at the position of the electrode via hole through the method of inkjet printing. For example, the material forming the second electrode may be conductive material such as conductive silver glue.

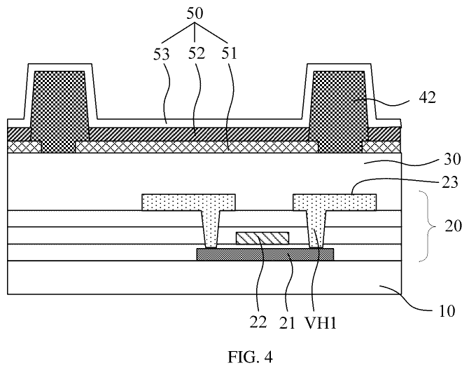

FIG. 4 schematically shows a cross-sectional view of a display substrate taken along line B-B in FIG. 2A according to some other embodiments of the present disclosure.

As shown in FIG. 4, in the region where the pixel opening is located, the planarization layer 30 disposed on a side of the driving circuit away from the base substrate 10 is not provided with an electrode via hole, so as to ensure the uniformity of the film layer of the generated light-emitting device. That is, in the region where the pixel opening is located, a light-emitting device 50 is disposed on a side of the planarization layer 30 away from the base substrate 10. The light-emitting device 50 includes a first electrode 51 (i.e. anode), a luminescent material layer 52, and a cathode 53. The luminescent material layer 52 is disposed on a side of the first electrode 51 away from the base substrate 10. The cathode 53 is disposed on a side of the luminescent material layer 52 away from the base substrate 10. By disposing the electrode via hole at the position of the first pixel defining portion of the first pixel defining layer, the impact of the electrode via hole on the planarity of the luminescent material layer of the light-emitting device is avoided, and the display effect of the light-emitting device is improved.

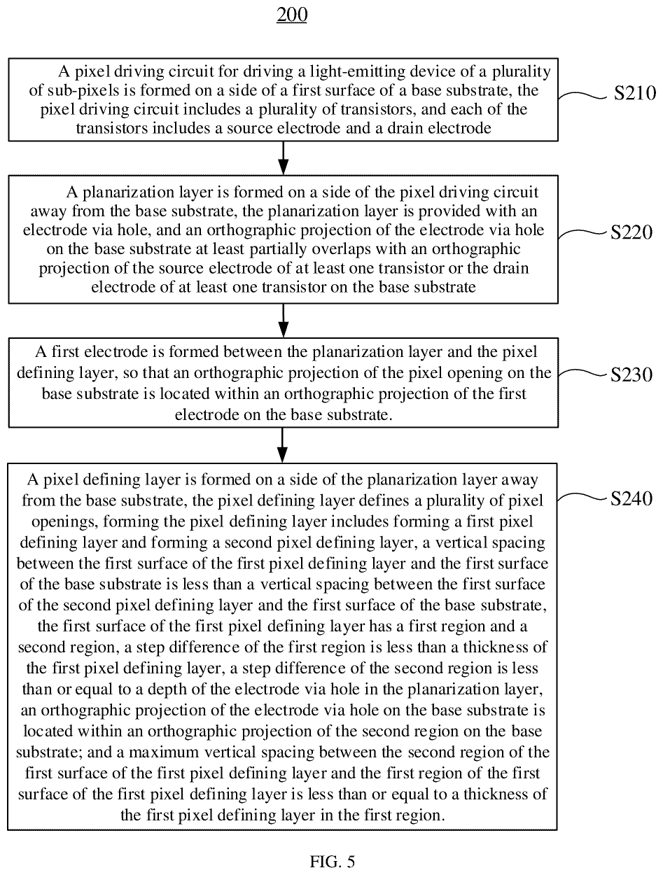

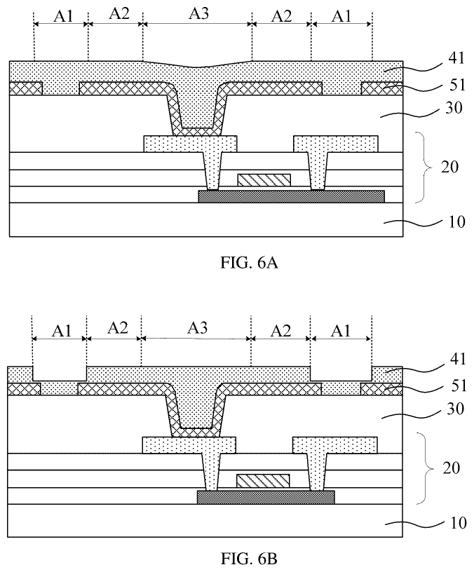

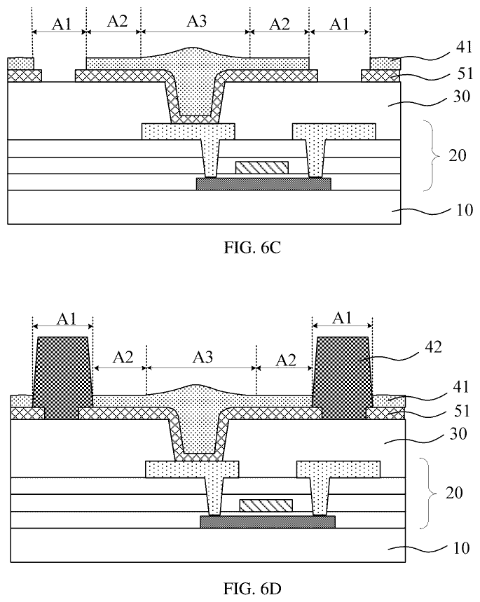

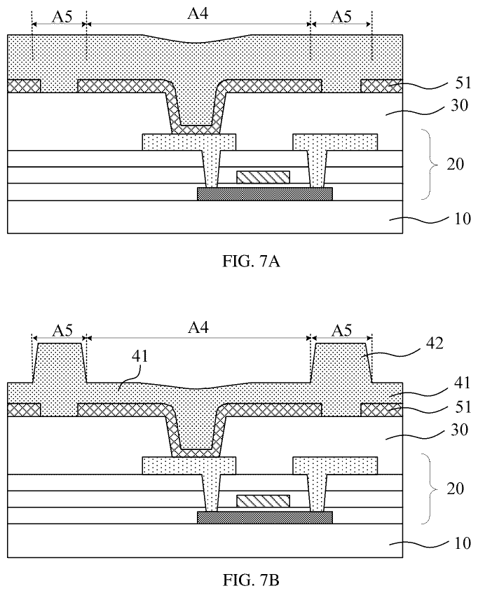

FIG. 5 schematically shows a flowchart of a method for manufacturing a display substrate according to some embodiments of the present disclosure. FIG. 6A to FIG. 6D schematically show cross-sectional views of a pixel defining layer formed by a method for manufacturing a display substrate according to some embodiments of the present disclosure. FIG. 7A to FIG. 7B schematically show cross-sectional views of a pixel defining layer formed by a method for manufacturing a display substrate according to some other embodiments of the present disclosure.

Another embodiment of the present disclosure provides a method for manufacturing a display substrate, as shown in FIG. 5. The process 200 of the method for manufacturing the display substrate of some embodiments of the present disclosure includes operation S210 to operation S240.

In operation S210, a pixel driving circuit for driving a light-emitting device of a plurality of sub-pixels is formed on a side of a first surface of a base substrate. The pixel driving circuit includes a plurality of transistors. Each of the transistors includes a source electrode and a drain electrode.

For example, the base substrate may be a high-temperature resistant quartz glass plate, or may also be a flexible substrate.

With reference to FIG. 3A, the operation S210 will be described in detail. For example, the specific process of forming the pixel driving circuit 20 on the first surface of the base substrate 10 includes: depositing one or more layers of silicon nitride and silicon oxide materials on the base substrate 10 sequentially through chemical vapor deposition (CVD), thereby obtaining a buffer layer of a stacked structure. A semiconductor layer 21 may be formed on the buffer layer. For example, by depositing a metal conductive oxide, which includes indium gallium zinc oxide or aluminum gallium tin oxide, on the buffer layer through physical vapor deposition (PVD), a semiconductor layer 21 is formed. A gate insulation layer is formed on the semiconductor layer. For example, by depositing a gate insulation layer through plasma enhanced chemical vapor deposition (PECVD), a gate layer 22 is further formed on the gate insulation layer. For example, the gate layer 22 may be deposited with metals such as Cr, W, Ti, Ta, Mo, Al, Cu and their alloy materials using physical vapor deposition method. Then, the gate layer 22 is obtained through processes such as coating photoresist, exposure, development and etching. An insulation material layer is formed on a side of the gate layer 22 away from the base substrate, and a source electrode and a drain electrode 23 are provided on a side of the insulation material layer away from the base substrate 10. The source electrode and the drain electrode 23 are electrically connected to the semiconductor layer 21 through the connecting via hole VH1.

In operation S220, a planarization layer is formed on a side of the pixel driving circuit away from the base substrate. The planarization layer is provided with an electrode via hole. An orthographic projection of the electrode via hole on the base substrate at least partially overlaps with an orthographic projection of the source electrode of at least one transistor or the drain electrode of at least one transistor on the base substrate.

For example, the planarization layer 30 may be formed by using chemical vapor deposition. For example, coating and covering a layer of silicon nitride to form an inorganic passivation layer on a side of the driving transistor included in the pixel driving circuit 20 away from the base substrate 10, and continuing to coat and cover a layer of polymethyl methacrylate to form an organic planarization layer on a side of the inorganic passivation layer away from the base substrate 10 through chemical vapor deposition. After forming the planarization layer 30, a photolithography pattern is formed through a photolithography process, and then an electrode via hole VH2 is formed in the planarization layer 30 using a dry etching process. The orthographic projection of the electrode via hole on the base substrate at least partially overlaps with the orthographic projection of the source electrode of the transistor or the orthographic projection of the drain electrode of the transistor on the base substrate, so that the source electrode of at least one transistor or the drain electrode of at least one transistor is electrically connected to the first electrode 51 in the display substrate through the electrode via hole VH2.

In operation S230, a first electrode is formed between the planarization layer and the pixel defining layer, so that an orthographic projection of the pixel opening on the base substrate is located within an orthographic projection of the first electrode on the base substrate.

The first electrode is electrically connected to the source electrode of at least one transistor or the drain electrode of at least one transistor through the electrode via hole.

An anode layer may be deposited on the planarization layer and in the electrode via hole. For example, by PVD, a layer of metal conductive oxide may be deposited on the planarization layer 30 and an inner side of the electrode via hole VH2 as the first electrode (such as the anode). For example, the metal conductive oxide may be ITO/Ag/ITO.

In operation S240, a pixel defining layer is formed on a side of the planarization layer away from the base substrate. The pixel defining layer defines a plurality of pixel openings. Forming the pixel defining layer includes forming a first pixel defining layer and forming a second pixel defining layer. A vertical spacing between the first surface of the first pixel defining layer and the first surface of the base substrate is less than a vertical spacing between the first surface of the second pixel defining layer and the first surface of the base substrate. The first surface of the first pixel defining layer has a first region and a second region. A step difference of the first region is less than a thickness of the first pixel defining layer. A step difference of the second region is less than or equal to a depth of the electrode via hole in the planarization layer. An orthographic projection of the electrode via hole on the base substrate is located within an orthographic projection of the second region on the base substrate. A maximum vertical spacing between the second region of the first surface of the first pixel defining layer and the first region of the first surface of the first pixel defining layer is less than or equal to a thickness of the first pixel defining layer in the first region.

The operation S240 of the embodiment of the present disclosure will be described in detail below with reference to FIG. 6A to FIG. 7B.

In some embodiments of the present disclosure, forming a pixel defining layer includes forming a first pixel defining layer and forming a second pixel defining layer.

As shown in FIG. 6A to FIG. 6D, a pixel defining layer material is formed on a side of the first electrode 51 away from the base substrate 10. For example, by covering a layer of silicon nitride through chemical vapor deposition (CVD), and then forming a first pixel defining layer 41 and a second pixel defining layer 42 through processes such as coating photoresist, exposure, development and etching. For example, the formed pixel defining layer includes a first pixel defining portion located in the first pixel defining layer 41 and a second pixel defining portion located in the second pixel defining layer 42. The first pixel defining portion extends in the first direction, and the second pixel defining portion extends in the second direction. The second pixel defining portion adjacent to the first pixel defining portion in the first direction and the first pixel defining portion adjacent to the second pixel defining portion in the second direction jointly define the pixel opening for accommodating the luminescent material.

As shown in FIG. 6A, after forming a pixel defining layer material on a side of the first electrode 51 away from the base substrate, when performing exposure, an exposure amount gradually decreases from an edge of the second region of the first surface of the first pixel defining layer towards a center of the second region of the first surface of the first pixel defining layer. For example, the exposure amount of the second region of the first surface of the first pixel defining layer is A3, the exposure amount of the first region of the first surface of the first pixel defining layer is A2, and the exposure amount of the region where the second pixel defining layer is located is A1. The exposure amount A1 is greater than the exposure amount A2, and the exposure amount A2 is greater than the exposure amount A3. For example, the exposure amount A3 may be zero, that is, not exposure, and the exposure amount A1 may be twice the exposure amount A2, that is, full exposure is performed on the region where the second pixel defining layer is located, half exposure is performed on the first region of the first surface of the first pixel defining layer, and no exposure is performed on the second region of the first surface of the first pixel defining layer. As shown in FIG. 6B to FIG. 6C, in the subsequent etching process, with the performance of etching, the thicknesses of the etched film layer in the regions with the exposure amount A1, the exposure amount A2 and the exposure amount A3 are different. For example, in the region of which the exposure amount is A1, the formed pixel defining layer material is completely etched, in the region of which the exposure amount is A2, the formed pixel defining layer material is partially etched, and in the region of which the exposure amount is A3, the formed pixel defining layer material is not etched, thereby generating a second region in the region of which the exposure amount is A3, which is a protruding portion in the region where the exposure amount is A3 as shown in FIG. 6C.

As shown in FIG. 6D, after forming the first pixel defining layer, the second pixel defining layer 42 may continue to be formed. For example, a material different from the material of the first pixel defining layer may be selected, that is, the pixel defining layer material may continue to be formed on a side of the first pixel defining layer away from the base substrate. When performing an exposure and an etching on the pixel defining layer material, an exposure amount of a region located in the first pixel defining layer is greater than an exposure amount of a region located in the second pixel defining layer. For example, a region located in the second pixel defining portion of the second pixel defining layer is not exposed, and other regions are fully exposed. In the subsequent etching process, the second pixel defining portion located in the second pixel defining layer 42 is generated.

In some exemplary embodiments of the present disclosure, as shown in FIG. 3C, the first pixel defining layer includes a first pixel defining sub-layer 41′ and a planarization portion 412 on a side away from the base substrate. After forming the first pixel defining sub-layer 41′ and/or forming the second pixel defining layer 42, the planarization portion 412 may be, for example, formed on a side of a first pixel defining sub-layer 41′ away from the base substrate through the method of exposure etching, so that an orthographic projection of the planarization portion on the base substrate is located within the orthographic projection of the electrode via hole VH2 on the base substrate.

In other embodiments of the present disclosure, the planarization portion 412 may be, for example, formed on a side of the first pixel defining sub-layer 41′ away from the base substrate through the method of inkjet printing, after forming the first pixel defining sub-layer 41′ of the first pixel defining layer and/or forming the second pixel defining layer 42, so that the orthographic projection of the planarization portion on the base substrate is located within the orthographic projection of the electrode via hole VH2 on the base substrate. When performing inkjet printing to form the planarization portion 412, the inkjet printing material may be, for example, polyimide, sulfonimide, epoxy resin, or other materials. Therefore, the planarization portion 412 has better planarization ability, and at the same time, it will not have a negative impact on the film thickness uniformity of the luminescent material in subsequent processes.

FIG. 7A and FIG. 7B schematically show schematic diagrams of a method for forming a film layer structure of a pixel defining layer of another embodiment. Forming a first pixel defining layer and a second pixel defining layer of the pixel defining layer includes: forming a pixel defining layer material on a side of the planarization layer 30 away from the base substrate 10; performing an exposure and an etching on the pixel defining layer material to simultaneously form the first pixel defining layer 41 and the second pixel defining layer 42. When performing an exposure and an etching on the pixel defining layer material, an exposure amount gradually decreases in a direction from the first pixel defining layer 41 towards the second pixel defining layer 42.

For example, an exposure amount gradually decreases from the first pixel defining portion of the first pixel defining layer 41 towards the second pixel defining portion of the second pixel defining layer 42. For example, an exposure amount of a region located in the first pixel defining portion of the first pixel defining layer 41 is A4, and an exposure amount of a region located in the second pixel defining portion of the second pixel defining layer 42 is A5. For example, if the exposure amount A4 is greater than the exposure amount A5, when performing etching, the second pixel defining portion of the second pixel defining layer 42 is formed in the region of which the exposure amount is A5. In this embodiment, a planarization portion may also be provided on a side of the first pixel defining layer away from the base substrate. According to the embodiments of the present disclosure, the process of manufacturing the pixel defining portion may be simplified, and costs may be reduced.

In some embodiments of the present disclosure, for the second electrode as shown in FIG. 3D, before forming the first electrode 51, the second electrode 511 may be formed on a side of the planarization layer 30 away from the base substrate through the method of inkjet printing. The second electrode 511 is located between the first electrode 51 and the source electrode of the transistor or the drain electrode of the transistor. The orthographic projection of the second electrode 511 on the base substrate is located within the orthographic projection of the electrode via hole on the base substrate. The second electrode is used to electrically connect the first electrode to the source electrode of at least one transistor or the drain electrode of at least one transistor.

In some embodiments of the present disclosure, forming the first electrode includes: forming the first electrode through exposure process, so that a step difference of a first surface of the first electrode in a first projection region is less than or equal to the thickness of the first pixel defining layer in the first region. The first projection region is formed by projecting the first region of the first pixel defining layer onto the base substrate, and the first surface of the first electrode is a surface of the first electrode away from the base substrate.

In some embodiments of the present disclosure, forming the planarization layer includes: forming the planarization layer through exposure process, so that a step difference of a first surface outside a second projection region of the planarization layer is less than or equal to the thickness of the first pixel defining layer in the first region. The second projection region is formed by projecting the second region of the first pixel defining layer onto the base substrate, and the first surface of the planarization layer is a surface of the planarization layer away from the base substrate.

In the embodiment of the present disclosure, since the pixel driving circuit is disposed on a side of the planarization layer 30 close to the base substrate, different wires will cause uneven changes in the thickness of the film layer. When forming the planarization layer through exposure process, for example, through adjusting the exposure amount of each position, such as digital exposure and other methods or halftone process, selective exposure may be performed on different regions, the planarity of the planarization layer may be achieved, thereby causing the first electrode formed on a side of the planarization layer away from the base substrate to be more planarized and effectively improving the display effect of the light-emitting device.

Another aspect of the present disclosure further provides a display device, including the display substrate as described above.

The beneficial effects that may be achieved by the display device in the embodiments of the present disclosure mentioned above are the same as those that may be achieved by the display substrate mentioned above, which will not be repeated here.

The above display device may be any device that displays images regardless of motion (such as video) or fixed (such as still image), and regardless of texts or images. More specifically, it is contemplated that the embodiments may be implemented in or associated with various electronic devices, such as (but not limited to) mobile phones, wireless devices, personal data assistants (PDAs), handheld or portable computers, GPS receivers/navigators, cameras, MP4 video players, cameras, game consoles, watches, clocks, calculators, TV monitors, flat panel displays, computer monitors, car displays (such as odometer displays, etc.), navigators, cockpit controllers and/or displays, camera view displays (such as rearview camera displays in vehicles), electronic photos, electronic billboards or signs, projectors, building structures, packaging and aesthetic structures (such as a display for an image of a piece of jewelry).

Although some embodiments of the entire concept of the present disclosure have been illustrated and explained, those of ordinary skill in the art will understand that changes may be made to these embodiments without departing from the principles and spirit of the entire invention concept. The scope of the present disclosure is limited by the claims and their equivalents.

1. A display substrate, comprising:
a base substrate comprising a first surface;
a plurality of sub-pixels disposed on a side of the first surface of the base substrate, wherein each sub-pixel comprises a light-emitting device and a pixel driving circuit for driving the light-emitting device, the pixel driving circuit comprises a plurality of transistors, and each of the transistors comprises a source electrode and a drain electrode;
a planarization layer located on a side of the pixel driving circuit away from the base substrate, wherein the planarization layer is provided with an electrode via hole, and an orthographic projection of the electrode via hole on the base substrate at least partially overlaps with an orthographic projection of the source electrode of at least one transistor or an orthographic projection of the drain electrode of at least one transistor on the base substrate;
a pixel defining layer disposed on a side of the planarization layer away from the base substrate, wherein the pixel defining layer defines a plurality of pixel openings; and
a first electrode disposed between the planarization layer and the pixel defining layer, wherein an orthographic projection of the pixel opening on the base substrate is located within an orthographic projection of the first electrode on the base substrate,
wherein the pixel defining layer comprises a first pixel defining layer and a second pixel defining layer, the first pixel defining layer comprises a first surface away from the base substrate, the second pixel defining layer comprises a first surface away from the base substrate, a vertical spacing between the first surface of the first pixel defining layer and the first surface of the base substrate is less than a vertical spacing between the first surface of the second pixel defining layer and the first surface of the base substrate, the display substrate comprises a first pixel defining portion and a second pixel defining portion, the first pixel defining portion is located in the first pixel defining layer and extends in a first direction, the second pixel defining portion is located in the second pixel defining layer and extends in a second direction, the first direction intersects with the second direction, and the first pixel defining portion and the second pixel defining portion define the pixel opening;
wherein the first surface of the first pixel defining layer has a first region and a second region, a step difference of the first region is less than a thickness of the first pixel defining layer, a step difference of the second region is less than or equal to a depth of the electrode via hole in the planarization layer, and an orthographic projection of the electrode via hole on the base substrate is located within an orthographic projection of the second region on the base substrate; and
wherein a maximum vertical spacing between the second region of the first surface of the first pixel defining layer and the first region of the first surface of the first pixel defining layer is less than or equal to a thickness of the first pixel defining layer in the first region.

2. The display substrate of claim 1, wherein a vertical spacing between the second region of the first surface of the first pixel defining layer and the first region of the first surface of the first pixel defining layer gradually increases from an edge of the second region towards a center of the second region.

3. The display substrate of claim 2, wherein the second region of the first surface of the first pixel defining layer protrudes relative to the first region of the first surface of the first pixel defining layer towards a direction away from the base substrate, and a protruding portion comprises a protruding point with a maximum spacing from the base substrate.

4. The display substrate of claim 3, wherein a vertical spacing between the protruding point and the first region of the first surface of the first pixel defining layer is less than or equal to the thickness of the first pixel defining layer in the first region.

5. The display substrate of claim 2, wherein the second region of the first surface of the first pixel defining layer recesses relative to the first region of the first surface of the first pixel defining layer towards a direction close to the base substrate, and a recessing portion comprises a recessing point with a minimum vertical spacing from the base substrate.

6. The display substrate of claim 5, wherein a vertical spacing between the recessing point and the first region of the first surface of the first pixel defining layer is less than or equal to a thickness of the first pixel defining layer in the first region.

7. The display substrate of claim 5, wherein the first pixel defining layer comprises a first pixel defining sub-layer, the recessing point is located on the first pixel defining sub-layer, and the vertical spacing between the recessing point and the first region of the first surface of the first pixel defining layer is greater than or equal to a thickness of the first pixel defining layer in the first region.

8. The display substrate of claim 7, wherein the first pixel defining layer further comprises a planarization portion disposed on a side of the first pixel defining sub-layer away from the base substrate, and an orthographic projection of the planarization portion on the base substrate is located within an orthographic projection of the electrode via hole on the base substrate.

9. The display substrate of claim 8, wherein the planarization portion comprises a first surface away from the base substrate, and a maximum vertical spacing between a first surface of the planarization portion and the first region of the first surface of the first pixel defining layer is less than the thickness of the first pixel defining layer in the first region.

10. The display substrate of claim 3, wherein a vertical spacing between the second region of the first surface of the first pixel defining layer and the first surface of the base substrate gradually increases from the edge of the second region towards the center of the second region.

11. The display substrate of claim 5, wherein the vertical spacing between the second region of the first surface of the first pixel defining layer and the first surface of the base substrate gradually decreases from the edge of the second region towards the center of the second region.

12. The display substrate of claim 1, wherein:
a first projection region is formed on the base substrate by the first region of the first pixel defining layer, and a second projection region is formed on the base substrate by the second region of the first pixel defining layer; and
the first electrode comprises a first surface away from the base substrate, and a step difference of the first surface of the first electrode in the first projection region is less than or equal to the thickness of the first pixel defining layer in the first region.

13. The display substrate of claim 12, wherein the planarization layer comprises a first surface away from the base substrate, and a step difference of the first surface outside the second projection region of the planarization layer is less than or equal to the thickness of the first pixel defining layer in the first region.

14. The display substrate of claim 8, wherein a material of the planarization portion comprises an organic material or an inorganic material.

15. The display substrate of claim 1, wherein the display substrate further comprises a second electrode between the first electrode and the source electrode of the transistor or the drain electrode of the transistor, an orthographic projection of the second electrode on the base substrate is located within an orthographic projection of the electrode via hole on the base substrate, and the second electrode is configured to electrically connect the first electrode to the source electrode of the transistor or the drain electrode of the transistor.

16. The display substrate of claim 1, wherein the orthographic projection of the first electrode on the base substrate partially overlaps with an orthographic projection of a second pixel defining portion adjacent to the first electrode in the first direction on the base substrate,
wherein an orthographic projection of the first pixel defining portion on the base substrate partially overlaps with an orthographic projection of the first electrode adjacent to the first pixel defining portion in the second direction on the base substrate, to form an overlapping region, and the electrode via hole is located in the overlapping region, and
wherein the first pixel defining layer comprises a hydrophilic material, and the second pixel defining layer comprises a hydrophobic material.

17-18. (canceled)

19. A method for manufacturing a display substrate, comprising:
forming a pixel driving circuit for driving a light-emitting device of a plurality of sub-pixels on a side of a first surface of a base substrate, wherein the pixel driving circuit comprises a plurality of transistors, and each of the transistors comprises a source electrode and a drain electrode;
forming a planarization layer on a side of the pixel driving circuit away from the base substrate, wherein the planarization layer is provided with an electrode via hole, and an orthographic projection of the electrode via hole on the base substrate at least partially overlaps with an orthographic projection of the source electrode of at least one transistor or an orthographic projection of the drain electrode of at least one transistor on the base substrate;
forming a pixel defining layer on a side of the planarization layer away from the base substrate, wherein the pixel defining layer defines a plurality of pixel openings; and
forming a first electrode between the planarization layer and the pixel defining layer before forming the pixel defining layer, so that an orthographic projection of the pixel opening on the base substrate is located within an orthographic projection of the first electrode on the base substrate,
wherein the forming the pixel defining layer comprises forming a first pixel defining layer and forming a second pixel defining layer, the first pixel defining layer comprises a first surface away from the base substrate, the second pixel defining layer comprises a first surface away from the base substrate, the pixel defining layer is formed, so that a vertical spacing between the first surface of the first pixel defining layer and the first surface of the base substrate is less than a vertical spacing between the first surface of the second pixel defining layer and the first surface of the base substrate;
wherein the method further comprises: forming a first pixel defining portion and forming a second pixel defining portion, the first pixel defining portion is located in the first pixel defining layer and extends in a first direction, the second pixel defining portion is located in the second pixel defining layer and extends in a second direction, the first direction intersects with the second direction, and the first pixel defining portion and the second pixel defining portion define the pixel opening;
wherein the first surface of the first pixel defining layer has a first region and a second region, a step difference of the first region is less than a thickness of the first pixel defining layer, a step difference of the second region is less than or equal to a depth of the electrode via hole in the planarization layer, and an orthographic projection of the electrode via hole on the base substrate is located within an orthographic projection of the second region on the base substrate; and
wherein a maximum vertical spacing between the second region of the first surface of the first pixel defining layer and the first region of the first surface of the first pixel defining layer is less than or equal to a thickness of the first pixel defining layer in the first region.

20. The method of claim 19, wherein forming the first pixel defining layer comprises:
forming a pixel defining layer material on a side of the planarization layer away from the base substrate; and
performing an exposure and an etching on the pixel defining layer material to form the first pixel defining layer, wherein when performing an exposure and an etching on the pixel defining layer material, an exposure amount gradually decreases from an edge of the second region of the first surface of the first pixel defining layer towards a center of the second region of the first surface of the first pixel defining layer,
wherein forming the second pixel defining layer comprises:
forming a pixel defining layer material on a side of the planarization layer away from the base substrate; and
performing an exposure and an etching on the pixel defining layer material to form the second pixel defining layer, wherein when performing an exposure and an etching on the pixel defining layer material, an exposure amount of a region located in the first pixel defining layer is greater than an exposure amount of a region located in the second pixel defining layer,
wherein the method further comprises:
forming a planarization portion on a side of a first pixel defining sub-layer comprised in the first pixel defining layer away from the base substrate through an exposure and an etching or an inkjet printing, wherein an orthographic projection of the planarization portion on the base substrate is located within the orthographic projection of the electrode via hole on the base substrate,
wherein the method further comprises:
forming a second electrode on a side of the planarization layer away from the base substrate through inkjet printing before forming the first electrode, wherein the second electrode is located between the first electrode and the source electrode of the transistor or the drain electrode of the transistor, an orthographic projection of the second electrode on the base substrate is located within the orthographic projection of the electrode via hole on the base substrate, and the second electrode is configured to electrically connect the first electrode to the source electrode of the transistor or the drain electrode of the transistor,
wherein forming the first electrode comprises:
forming the first electrode through exposure process, so that a step difference of a first surface of the first electrode in a first projection region is less than or equal to the thickness of the first pixel defining layer in the first region,
wherein the first projection region is formed by projecting the first region of the first pixel defining layer onto the base substrate, and the first surface of the first electrode is a surface on a side of the first electrode away from the base substrate,
wherein forming the planarization layer comprises:
forming the planarization layer through exposure process, so that a step difference of a first surface outside a second projection region of the planarization layer is less than or equal to the thickness of the first pixel defining layer in the first region, and
wherein the second projection region is formed by projecting the second region of the first pixel defining layer onto the base substrate, and the first surface of the planarization layer is a surface on a side of the planarization layer away from the base substrate.

21-23. (canceled)

24. The method of claim 19, wherein forming a first pixel defining layer and forming a second pixel defining layer comprise:
forming a pixel defining layer material on a side of the planarization layer away from the base substrate; and
performing an exposure and an etching on the pixel defining layer material to simultaneously form the first pixel defining layer and the second pixel defining layer,
wherein when performing an exposure and an etching on the pixel defining layer material, an exposure amount gradually decreases in a direction from the first pixel defining layer towards the second pixel defining layer.

25-27. (canceled)

28. A display device comprising a display substrate of claim 1.
